(19) United States
(12) Patent Application Publication
(10) Pub. No.: US 2003/0047348 A1
(43) Pub. Date: Mar. 13, 2003

(54) Grid array mounting arrangements

(76) Inventors: Rebecca Jessep, Dallas, OR (US); Ray Askew, Hillsboro, OR (US); Daryl Sato, Beaverton, OR (US); Jeff Krieger, Portland, OR (US); Phil Geng, Portland, OR (US)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/949,118

(22) Filed: Sep. 10, 2001

(51) Int. Cl. H05K 1/00

(52) U.S. Cl. 174/250; 174/261; 174/262; 257/786

(57) ABSTRACT

Grid array mounting arrangements, including apparatus (sub-arrays, arrays, electronic components, systems) and methods.

### FIELD

The present invention is directed to grid array mounting arrangements.

### BACKGROUND

Mounting and packaging technologies of semiconductor circuits appear to be continuously in transition, with the continuing goals to achieve, for example, greater ease in mounting, lower manufacturing costs, more reliable mounting and packaging, and reduction in size and weight. One mounting and packaging technology which has gained high popularity is that of grid array technologies, for example, ball grid arrays (BGAs), plastic BGAs (PBGAs), organic lan grid arrays (OLGAs), etc. Needed are improved arrangements which allow grid array mounting and packaging technologies to be more successfully implemented and further improved.

### BRIEF DESCRIPTION OF THE DRAWINGS

The foregoing and a better understanding of the present invention will become apparent from the following detailed description of example embodiments and the claims when read in connection with the accompanying drawings, all forming a part of the disclosure of this invention. While the foregoing and following written and illustrated disclosure focuses on disclosing example embodiments of the invention, it should be clearly understood that the same is by way of illustration and example only and that the invention is not limited thereto. The spirit and scope of the present invention are limited only by the terms of the appended claims.

The following represents brief descriptions of the drawings, wherein:

FIG. 1 relates to a perspective view of an example system including an example flip chip pin grid array (FC-PGA) arrangement, such FIG. being useful in explanation and understanding of background and example embodiments of the present invention;

FIG. 2 is a bottom (secondary side) view 200 of the example FIG. 1 FC-PGA substrate;

FIG. 3 is a plan view of an example background shifted interleaved pad/via array pattern useable on a primary side of the example FIG. 1 FCP-GA substrate;

FIG. 4 is a plan view (similar to FIG. 3) of an example non-shifted interleaved pad/via array pattern using an example via between pad (VBP) array pattern according to one example embodiment of the present invention;

FIG. 5 is a magnified partial cross-sectional view of a part of the FIG. 1 FC-PGA system as taken along the FIG. 1 cross-sectional line 5-5, such view being useful in explanation and understanding of background and example embodiments of the present invention;

FIG. 6 is an enlarged, more detailed view of a portion of the FIG. 3 example array;

FIG. 7 is an enlarged, more detailed view of a portion of the FIG. 4 example VBP array;

FIG. 8 is a simplistic plan view of a sample portion of an array, and further having routing traces (R-traces), such figure being useful in illustrating example R-trace routing failures with respect to arrays laid out in the manner of FIGS. 3 and 6;

FIG. 9 is a simplistic plan view of an example VBP array portion, and further having R-traces, such figure being useful in illustrating example R-trace routing successes with respect to arrays laid out in the manner of FIGS. 4 and 7;

FIGS. 10 and 11 are simplified cross-sectional views as taken along cross-sectional line 10-10 in FIG. 7 before and after the FIG. 7 arrangement is subjected to a BGA mounting operation, such views being useful in illustrating example solder joint, solder mask and plugging arrangements according to a first example embodiment of the present invention, as well as example problems with the solder joints after a solder jointing operation;

FIGS. 12 and 13 are simplified cross-sectional views similar to those of FIGS. 10-11, such views being useful in illustrating example solder joint (SJ), solder mask (SM) and plugging arrangements according to another example embodiment of the present invention;

FIG. 14 is a simplified plan view similar to that of FIG. 7, such view illustrating another example VBP array layout, where pad-to-via (PV) traces have been eliminated and the pads and vias being provided in a touching or overlapping arrangement;

FIG. 15 is an example manufacturing process flow for printed circuit board (PCB) substrate production, and further shows three example process flow alternatives with respect to three differing example embodiments of the present invention;

FIG. 16 is a simplified plan view of an example SM layout useable with a secondary-side-plugged substrate example embodiment of the present invention;

FIG. 17 is a simplified plan view (similar to FIG. 16) of an example SM layout useable with a primary-side-plugged substrate example embodiment of the present invention;

FIG. 18 is a plan view of an example BGA primary side breakout layout on a primary side of a BGA substrate, such view being useful in explanation and understanding of pad/via and R-trace (including breakout trace (B-trace)) areas of the substrate, as well as a trace density within the pad/via array area;

FIG. 19 is a plan view (similar to FIG. 18) of an example BGA primary side breakout layout using VBP array patterns on a primary side of a BGA substrate, such view being useful in explanation and understanding of pad/via and R-trace (including B-trace) areas of the substrate, as well as a trace density within the pad/via array area;

FIG. 20 is a magnified, partial cross-sectional view of the FIG. 11's area 20, such view being useful in explanation and understanding of a cracking phenomena with respect to a collapsed solder ball bridge;

FIG. 21 is a simplified plan layout designating various areas of the FIG. 20 breakout layout, such view being useful in explanation and understanding of further aspects of the FIG. 20 VBP example layout embodiment of the present invention; and

FIG. 22 (similar to FIG. 4) is a plan view of an example non-shifted interleaved pad/via array pattern using an example via between pad (VBP) array pattern according to another example embodiment of the present invention, where pad-rows and via-rows are alternated in groups of two in a column direction.

### DETAILED DESCRIPTION

Before beginning a detailed description of the subject invention, mention of the following is in order. When appropriate, like reference numerals and characters may be used to designate identical, corresponding or similar components in differing figure drawings. Further, in the detailed description to follow, example sizes/models/values/ranges may be given, although the present invention is not limited to the same. Further, the drawings may not be to accurate dimensional scale. Example arbitrary axes (e.g., X-axis, Y-axis and/or Z-axis) and/or example arbitrary column (C) and row (R) may be discussed/illustrated, although practice of embodiments of the present invention is not limited thereto (e.g., differing axes directions may be able to be assigned, and the C and R designations may be able to be reversed). Well-known power/ground connections to substrates, ICs and other components may not be shown in great detail within the FIGs. for simplicity of illustration and discussion, and so as not to obscure the invention. Further, arrangements may be shown in simplistic diagram form in order to avoid obscuring the invention, and also in view of the fact that specifics with respect to implementation of such diagram arrangements are highly dependent upon the platform within which the present invention is to be implemented, i.e., such specifics should be well within purview of one skilled in the art. Where specific details are set forth in order to describe example embodiments of the invention, it should be apparent to one skilled in the art that the invention can be practiced without, or with variation of, these specific details.

While the following detailed description will describe example embodiments in the context of an example FC-PGA arrangement, practice of the present invention is not limited to such context, i.e., practice of the present invention may have uses with other types of chips and with other types of mounting and packaging technologies, e.g., flip chip ball grid array (FC-BGA) substrates, interposers, and PCBs such as motherboards. That is, while FIG. 1 illustrates the substrate 110 in a form of a FC-PGA using pins on the bottom of the substrate, the substrate may itself use a BGA instead of a PGA for electrical mounting of the substrate 110 to another substrate (e.g., an interposer, or a larger motherboard), whereupon VBP layout arrangements of the present invention may likewise be useable with respect to the substrate's BGA. Further, while the example embodiments are described with the die having an example solder BGA, practice of embodiments of the present invention is not limited to grid arrays using a ball shape or to solder material for a jointing material, e.g., practice may be had with bumped grid arrays (BUGA) in general, a further non-limiting listing including a (plastic) PBGA, a (ceramic) CBGA, an organic Ian grid array (OLGA).

Turning now to detailed description, FIG. 1 relates to a perspective view of an example electronic system including a FC-PGA system arrangement 100, such FIG. being useful in explanation and understanding of background and example embodiments of the present invention. More particularly, FIG. 1 illustrates an integrated circuit (IC) PCB carrier package system, and more particularly, an example FC-PGA system including a substrate 110 having a FC 120 mounted thereto, FC under-fill 125, pins 130, die (primary) side components (DSCs) 140, a plurality of exposed electrical pads (lands) and/or vias 150, electrical R-traces 152, and an indexing mark 160.

The substrate 110 may be, for example, a fiber-reinforced (FR) resin substrate, the FC 120 may be a FC die having a solder-bumped BGA interconnection scheme on a bottom thereof, which electrically interconnects with a pad/via array on substrate 110, and the under-fill 125 may be an epoxy under-fill. The pins 130 may be arranged in a PGA, and may be formed of copper alloy or Kovar material which is plated with nickel (Ni) and gold (Au). The die side components (DSCs) 140 are optional, and may be, for example, decoupling capacitors or resistors. In some industry embodiments, DSCs may be prohibited from a die side of the substrate. The exposed electrical pads/vias 150 and electrical R-traces may be, for example, exposed laminate interconnections (described hereinafter). Finally, the indexing mark 160 may be a gold-colored triangle, and serve as an index for, for example, a pin number 1.

The FC-PGA 100 may further include (not shown) an integrated heat spreader (IHS) mounted on top of FC die 120 through a thermal interface agent such as thermal grease or conductive epoxy. The IHS may be of any suitable size, and be made of any suitable material, for example, nickel-coated copper. A heat sink (not shown) may in turn be mounted on top of the IHS, or even directly on the FC die 120, again using a thermal agent. The FC-PGA arrangement is, in turn, insertable (indicated by arrow 70) into a socket 80 of an electronic system 90 (e.g., a notebook computer, cell phone, PDA, etc.).

Continuing on to further FIGs., FIG. 2 is a bottom (secondary side) view 200 of the example FIG. 1 FC-PGA substrate. More specifically, the bottom 210 may include pins 130 arranged in the bottom (or pin) side PGA layout, and may further include pin side components (PSCs) 240 (e.g., decoupling capacitors and resistors). FIG. 2 also illustrates various industry dimensional notations (D, D1, G1, G2 and H) not important to discussion of the present invention.

At this point, it is useful to stress again that pad/via array embodiments of the present invention may be practiced on an interposer surface, a PCB (e.g., motherboard) surface, and many other bonding surfaces/substrates in addition to the example illustrated/discussed FC-PGA substrate. Accordingly, in interpreting the scope of the described/claimed invention, the pad/via substrate 110 should be viewed as any generic substrate having pad/via array embodiments of the present invention formed thereon. For example, embodiments of the present invention may be particularly useful in bonding IC processors having a BGA thereon, onto a motherboard PCB. The die 120 should similarly be viewed generically, i.e., the die 120 should be viewed as any generic substrate (e.g., die, interposer, PCB, etc.) having an interfacing grid array (e.g., BGA) thereon. For example, embodiments of the present invention may be useful in bonding an interposer PCB having a BGA thereon, onto a motherboard PCB having a pad/via array (according to the present invention) thereon.

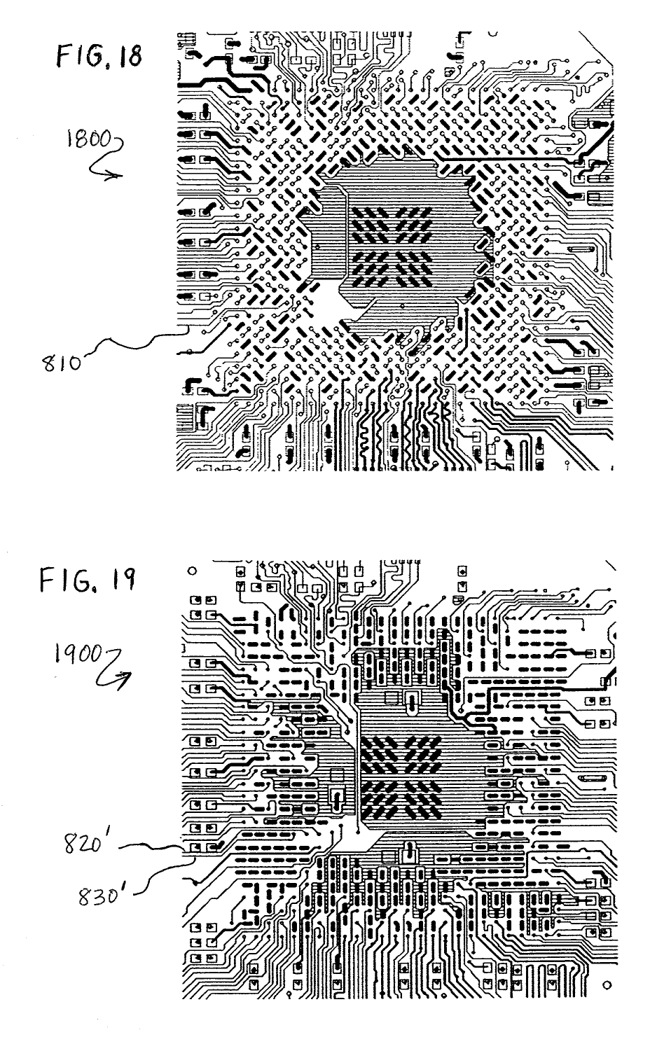

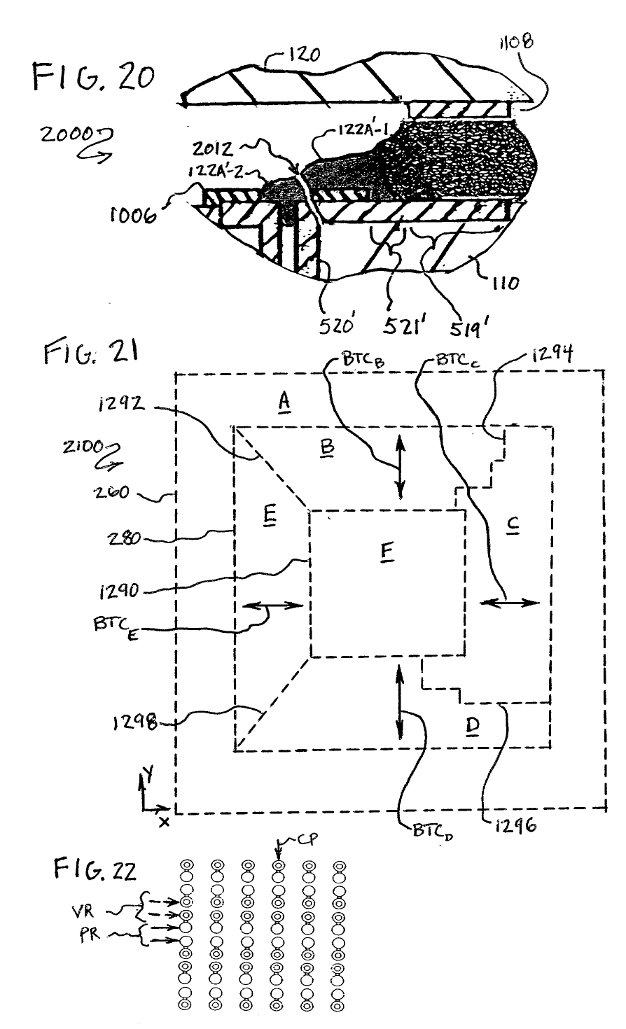

Further shown in a central portion of the FIG. 2 bottom view in phantom line form is an example of a location/layout of a primary side's mounting area which may be used for mounting of the FC die 120 to the substrate 110 on a primary surface thereof. More particularly, the mounting area is shown subdivided into an array area 280 containing mainly pads and vias in an array pattern, whereas an area defined between the array area 280 and phantom line 260 represents a R-trace area having mainly R-traces therein. For better understanding of such areas, attention is directed to FIGS. 18 and 19 (discussed further ahead) which show example BGA primary side breakout layout patterns. Such FIGS. 18 and 19 more clearly show the central array area and R-trace area in an example real-world implementation, rather than the FIG. 2 representative dashed-line area form. Further, FIG. 21 (discussed ahead) designates example layout boundaries of further example sub-areas of the central array area.

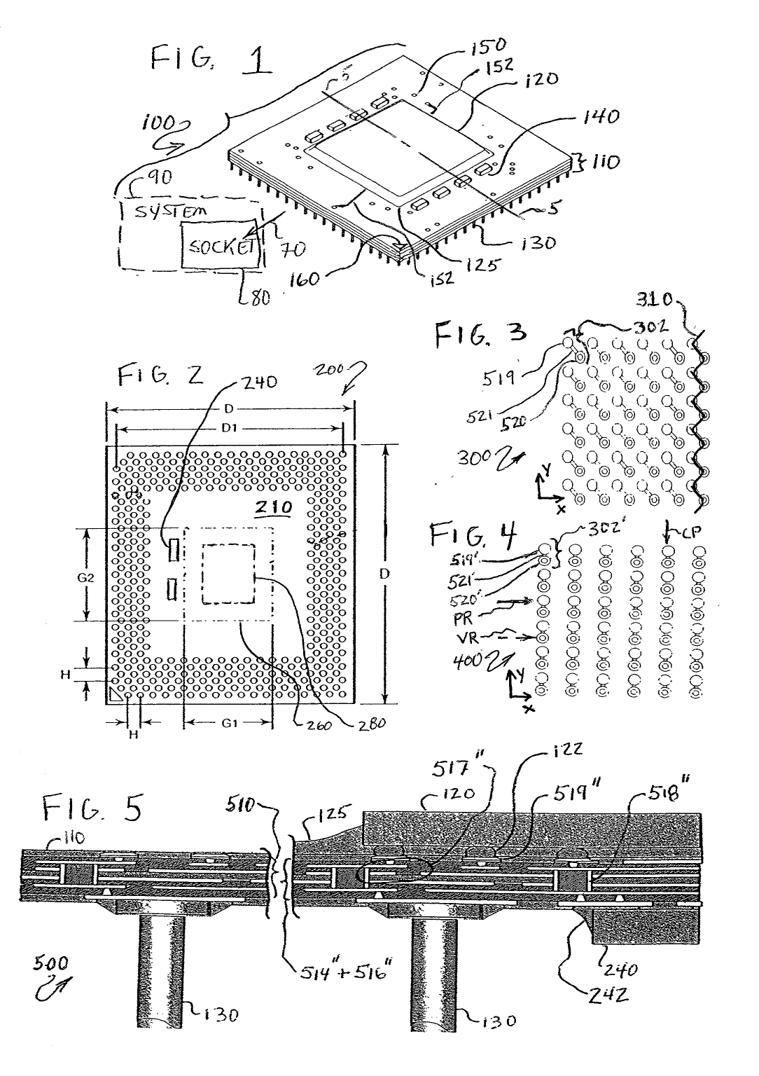

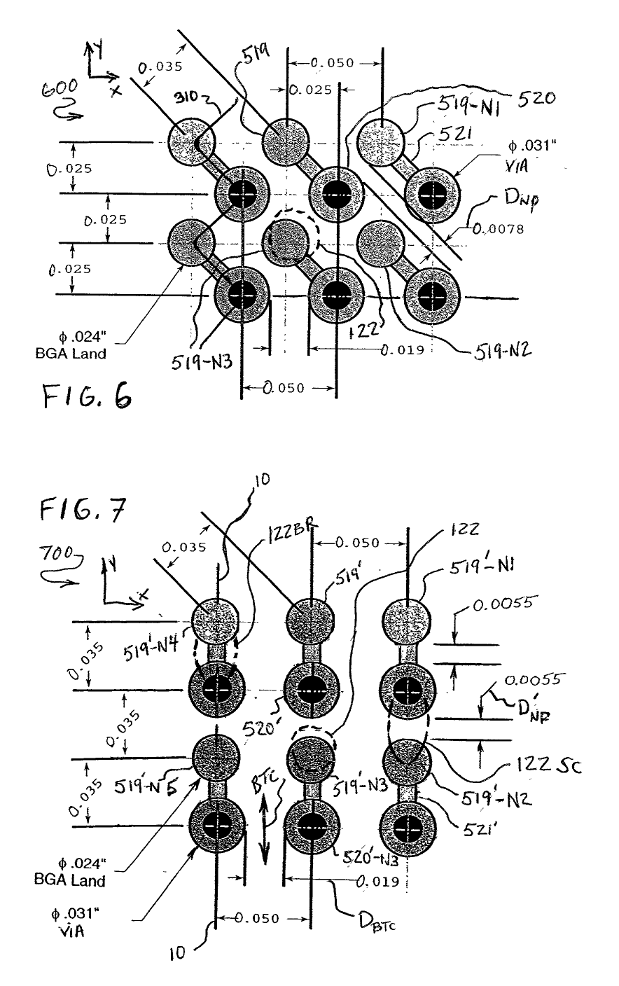

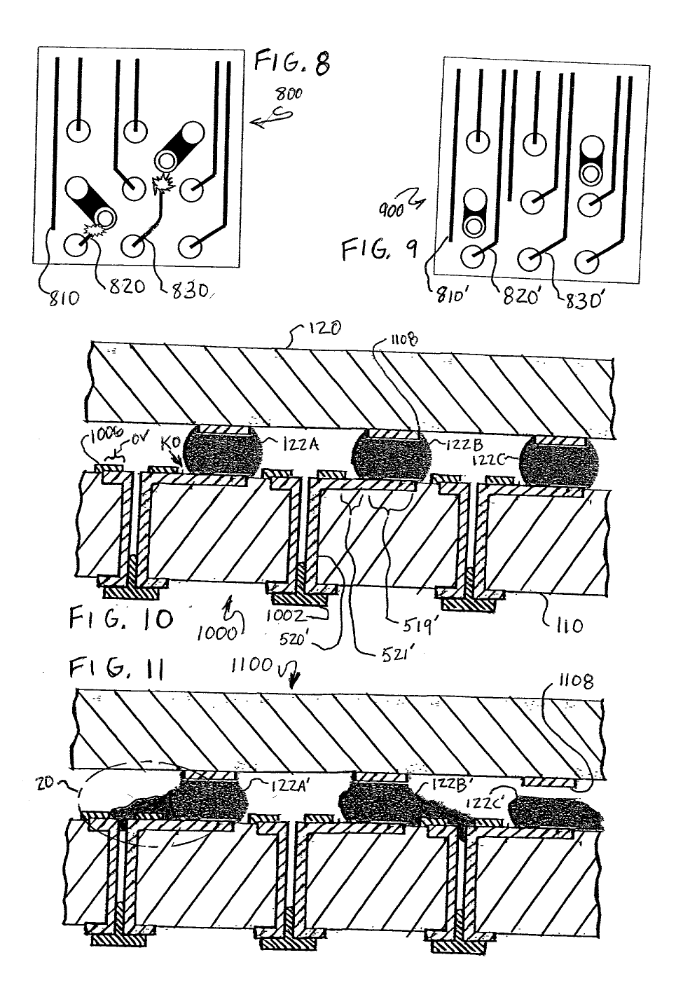

FIG. 3 is a plan view of an example background shifted interleaved array pattern, and FIG. 4 is a plan view of an example non-shifted interleaved via between pad (VBP) array pattern. Discussion will return soon to such FIGs. after an initial brief description of FIG. 5.

That is, turning to FIG. 5, FIG. 5 is a magnified partial cross-sectional view of a part of the FIG. 1 FC-PGA system as taken along the FIG. 1 cross-sectional line 5-5, such view being useful in explanation and understanding of background and example embodiments of the present invention. More particularly, the magnified partial cross-sectional view 500 more clearly illustrates that the FC-PGA substrate 110 is a pinned, laminated PCB structure in the form of an organic structure including an internal core which may be, for example, a FR substrate formed of bismaleimide triazine (BT) resin reinforced with glass fiber, with a transition temperature (Tg) ranging from 1651-1751 C. The core may typically be 0.7-0.8 mm in thickness, and further, may be associated with additional multi-laminate layers 510. More particularly, primary (die) side laminate layers 514″ may be provided on a primary (die) side, whereas secondary (e.g., pin) side laminate layers 516″ may be provided on a secondary side of the substrate 110. The multi-laminate layers generally contain additional power, ground and signaling interconnects 517″, for example, in the form of copper traces separated by dielectric layers, so as to provide, for example, electrical interconnections between the pins 130 and the substrate pads 519 (which, in turn, interface with and electrically interconnect to the FC bumps 122 of the FC 120).

Further included as substrate interconnection structures are via holes 518″ drilled at least partly through the PCB 510 including the laminate layers 514″, 516″, so as to form a passageway there through. Such vias have internal sides thereof coated with electrically-conductive material (e.g., copper) to provide appropriate interlayer electric conduction paths. As further features, the FC 120 is more clearly shown as having a FC under-fill 125 associated therewith for bonding and hermetic sealing, while PSCs 240 are more clearly shown as having a PSC under-fill 242 associated therewith for bonding and hermetic sealing.

Whereas an internal core layer of the substrate typically may be, for example, 0.7-0.8 mm in thickness, the laminate layers 514″, 516″ may be, for example, constructed of a plurality of 15 μm copper interconnect laminate layers, and, for example, 30 μm dielectric laminate layers. Overall, a thickness dimension of the substrate 110 may be, for example, in a thickness range of 1.0-1.2 mm. In contrast, the die 120 may be, for example, in a thickness range of 0.6-0.9 mm, and typically may be 0.8 mm.

The FIG. 5 example substrate arrangement is advantageous in that the thick core 510 affords a high degree of rigidity or stiffness to the FC-PGA substrate 110 such that, when the FC 120 is mounted and interconnected to the substrate 110 via high pressure and heat (i.e., a high temperature thermo-bonding process), the FIG. 5 FC-PGA experiences no, or a negligible amount of, bending and flexing. Accordingly, the FC 120 can be securely and reliably mounted and interconnected (solder jointed) to the substrate 110.

Returning now to more detailed description of FIG. 3, FIG. 3 is a plan view of an example background shifted interleaved pad/via array pattern 300 useable on a primary side of the example FIG. 1 FC-PGA substrate, i.e., the array pattern is shown distributed in designated X and Y directions. More particularly, included is a large plurality of pad/via pairs 302, which each pair including a pad (land) 519, a via 520 (including a via-pad on a primary side surface of the substrate, as well as a passageway at least partially through the substrate), and a pad/via (PV) trace 521. FIG. 6 is an enlarged, more detailed view 600 of a portion of the FIG. 3 example array. Such FIG. 6 includes example, non-limiting dimensions (shown in inches); only dimensions of particular interest to explanation and understanding of the present invention will be discussed.

One main feature of the shifted interleaved array 300 is that each via 520 (see FIG. 6) is shifted or skewed or staggered in an X and Y direction out of column alignment from its associated (electrically connected) pad 519, such that the via 520 is provided at an interstitial position with respect to the combination of its associated pad 519 and three neighboring pads 519-N1, 519-N2 and 519-N3. More particularly, such pad 520 is illustrated as having an example neighboring pad (NP) clearance distance DNP (0.0078 inches), which may be the same clearance distance (approximately equidistant) for all three of the neighboring pads 519-N1, 519-N2 and 519-N3. Since the pad 520 (see FIG. 6) is so shifted or skewed out of alignment with its associated pad 519, the via 520 does not have any portion of its body thereof interposed between neighboring pads in the same column to which it is associated.

The above-described interstitial position is advantageous in that a maximum tolerance for ball-to-pad mis-registration is accommodated. More particularly, the phantom circle 122 in FIG. 6 represents an example solder ball or bump mis-registered to the pad 519-N3 during mounting, i.e., wherein the solder ball 122 is not properly aligned to the pad 519-N3. As it can be seen from FIG. 6, even with such a high degree of mis-registration, disadvantageous (e.g., short-circuiting) electrical contact with the neighboring via 520 is still avoided.

In contrast, such arrangement is disadvantageous in that the shifted interleaved array provides no unobstructed routing paths (e.g., straight-line channels) to accommodate R-traces between the pad/via pairs 302. More particularly, as can be seen in either FIG. 3 or FIG. 6, pads 519 within a same (first) column each have a shifted, skewed or staggered vias 520 (in a second column) such that pad/via pairs 302 in a Y-direction form a zigzagged pattern as shown representatively by the FIG. 3 line 310. It should be further apparent from such FIG. that zigs of one Y-direction group closely nestle within the zags of a neighboring Y-direction group. Accordingly, it can be seen from FIG. 6 that there are no unobstructed straight-line paths in either of the X or Y directions. Further, the straight-line diagonal paths through the array contain insufficient clearance between opposing pads and vias (e.g., 519-N1 and 520), so as to avoid electrical interferences (e.g., short circuits).

To further clarify the obstructed R-trace routing paths, attention is directed momentarily to FIG. 8. More particularly, FIG. 8 is a simplistic plan view 800 of a sample portion of an array, and further has R-traces. Such figure is useful in illustrating example R-trace routing failures with respect to arrays laid out in the manner of FIGS. 3 and 6. Further detailing FIG. 8, shown is a first trace 810 which is able to be provided in an unobstructed manner. In contrast, additionally shown are further traces 820, 830 which encounter obstructions (illustrated representatively by explosions) when attempting to traverse through a shifted interleaved array 800, i.e., such traces would collide with shifted or skewed pad/via pairs and electrically short-circuit therewith.

FIG. 18 showing the example BGA primary side breakout layout pattern 1800 illustrates the successful R-trace 810 as well as examples of other R-traces successfully extending into the shifted or skewed array. Throughout this disclosures, R-traces successfully extending into a pad/via array breakout area may sometimes be called breakout traces (B-traces).

The FIG. 18 successful routings are accomplished mainly indirectly. More particularly, one can easily note in viewing FIG. 18 that the successful B-trace routings almost invariably have been accomplished by the removal of one or more pad/via pairs from the array to provide a routing path. While the FIG. 18 example does illustrate a minimum amount of B-traces routing between intact pad/via pairs (i.e., inter-pair routings), such are the exception rather than the rule. That is, inter-pair B-trace routings are very difficult to achieve within the FIGS. 3 and 6 shifted, interleaved array arrangement, due to constraints of manufacturing tolerances/mis-registrations. Thus, the inter-pair B-trace routings are used only sparingly (if at all) during design and manufacturing. What is needed is an arrangement which accommodates inter-pair B-trace routings with greater ease and flexibility.

Turning next to FIG. 4, FIG. 4 is a plan view of an example non-shifted interleaved pad/via array pattern 400 using an example via between pad (VBP) array pattern according to one example embodiment of the present invention. Again shown, are a plurality of pad/via pair members 302′, each again having a pad 519′, via 520′ and PV-trace 521′. Such VBP array can be described in any number of different ways. For example, the VBP array may be described as being characterized by the distinctive feature of the vias being provided behind or between neighboring pads within a column, i.e., the via 520′ is provided aligned within the same column as neighboring pads within the column, instead of being shifted, skewed, or staggered out of the column.

In one example VBP embodiment, for at least a majority of the plurality of pad/via pairs, the via of the pads which are arranged in the same column (see, for example, the columned-pair CP arrow in FIG. 4) has an axis of the body thereof substantially collinear with axes of the bodies of the neighboring pads in the same column (see any of FIGS. 4, 7, 14 or 22, and especially FIG. 7). Such collinear alignment is advantageous in that it affords maximum inter-column spacing, such spacing being useable for the routing of R-traces. However, practice of the present invention is not limited to substantially collinear pad/via alignments.

More particularly, the via of pads which are arranged in the same column may simply have at least a majority of the body thereof interposed between the neighboring pads in the same column, or even only a portion of a body thereof interposed between neighboring pads in the same column. The interposed majority and portion embodiments are less advantageous (over the collinear embodiment) in that some of the inter-column spacing gets used up by the non-collinear pad/via pairs, and therefore less inter-column spacing will be available for R-trace routing.

Another way the example FIG. 4 VBP array can be described is as follows. More particularly, the VBP sub-array is arranged in a substantially rectilinear array where, in addition to the pad and via of pad/via pairs in a same column-direction being more collinear (over that of the FIG. 3 array), pads of adjacent pad/via pairs in adjacent columns (see, for example, the pad row PR arrow in FIG. 4) are substantially collinear with one another in a row-direction, and vias of adjacent pad/via pairs in adjacent columns (see, for example, the via row VR arrow in FIG. 4) are substantially collinear with one another in the row-direction. Practice of the present invention may not be limited to a PR and VR layout.

Another possible feature of the example VBP arrays is that of PR and VR repetitiveness. More particularly, FIGS. 4 and 7 illustrate one example embodiment where pad-rows and via-rows are provided in a predetermined repetitive pattern along the column-direction, i.e., FIGS. 4 and 7 show the pad-rows PR and via-rows VR alternating one-by-one with each row in the column direction. Practice of embodiments of the present invention is not limited thereto.

For example, FIG. 22 illustrates another example embodiment where pad-rows PR and via-rows VR are provided in pairs which alternate in the column direction. Note that pads of adjacent pad/via pairs within a column are placed in a back-to-back manner, and similarly note the same with respect to the vias of adjacent pad/via pairs. Such back-to-back example embodiment may be advantageous in that each solder ball for jointing to a pad/via pair is not positioned close to any vias not associated therewith (not electrically connected thereto using a PV-trace), thereby reducing the potential for via-bridging (described ahead). Typically, since pad-via pairs are arranged in a more collinear manner with embodiments of the present invention, a number of pad-rows and a number of via-rows for a column may be substantially equal to one another.

FIG. 7 is an enlarged view 700 of a portion of the FIG. 4 VBP array. Again, example, non-limiting dimensions are shown; and again, particular dimensions of interest will be discussed where appropriate.

The FIG. 7 enlarged view illustrates an example embodiment of a VBP layout technology adapted to improve the trace routing issue. As can be more clearly seen over that of FIG. 4, the via 520′ is relocated from its disadvantageous interstitial position between four diagonal solder pads (519, 519-N1, 519-N2-519-N3; FIG. 6) to positions between two vertical (Y axis) pads (519′, 519′-N3; FIG. 7). That is, the VBP grid component land patterns are based on a more collinear alignment of the grid array vias with the grid array pads (see, e.g., collinear alignment of the 519′/520′ and 519′-N3/520′-N3 pairs), so as to provide channels between the grid array pads/vias that allow a PCB designer to increase signal breakout density from a component and improve the power delivery to the component.

More particularly, FIG. 7 illustrates an example breakout trace channel (BTC) formed between the vertical grid columns, with an example clearance distance (0.019″) of such BTC being illustrated with a DBTC designation. Accordingly, it can easily be seen that the arrangement of FIGS. 4 and 7 is advantageous in that trace reading paths or channels of sufficient (i.e., a predetermined) clearance are provided between grid columns (or grid rows).

Regarding the BTCs, FIG. 9 (similar to FIG. 8) is a simplistic plan view 900 of an example VBP array portion, and further having R-traces within BTC channels. Such figure is useful in illustrating example R-trace routing successes with respect to arrays laid out in the manner of FIGS. 4 and 7. Shown are R-traces 810′, 820′ and 830′ which are able to be provided in an unobstructed manner.

Extending the FIG. 9 discussion further, attention is directed to FIG. 19 (similar to FIG. 18), which illustrates an example BGA primary side breakout 1900 using a VBP array pattern. In comparison to the FIG. 18, it can be seen that the FIG. 19 breakout using a VBP array pattern is advantageous in that there is achieved a greater density of R-traces extending (e.g., as B-traces) into the central array area (see 280 in FIG. 2 for overview). Such is advantageous in a number of regards.

First, because additional B-traces can now be provided on a surface of the substrate 110, fewer lamination layers (see FIG. 5) may be needed for the substrate 110. Such results in thinner, FC-PGA substrates, as well as electronic packages. That is, any substrate (e.g., interposer, PCB (e.g., motherboard), etc.) using the VBP array arrangement on a surface thereof, may have fewer lamination layers and thus be thinner. Second, because less complicated laminate layer routing is required, the laminate layers are easier to design, thus a faster time to market (TtM) is achieved. Third, greater capacitance may be realized.

More particularly, the capacitance realizable from PCB layer shape fills is directionally proportional to surface area. An increase in surface area yields a linear increase in available capacitance. Typical PCBs manufactured using FR4 dielectric (eᵣ=4.5) provide ˜500 pF/sq. inches of capacitance for outer layer shape fills over a 4 mil. prepreg. thickness. Localized capacitance under a grid array component provides better high frequency (HF) decoupling for the device due to its close proximity to the device. The closer capacitance is to a device pin, the lower the inductance between the capacitance and the pins.

Accordingly, using a VBP array according to the present invention may result in the further advantage that ones of the DSCs 140 (FIG. 1) and/or PSCs 240 (FIGS. 2 and 5) may be able to be omitted and instead provided by PCB layer shape fills on a surface of the substrate (e.g., under the die). For example, decoupling capacitors may be provided by patterned trace shapes rather than discrete components added later to the substrate 110. That is, embodiments of the present invention provide an ability to achieve limited on-package decoupling without the need for discrete components to be assembled onto the substrate. The advantages are improved electrical performance and power delivery at basically a zero net cost increase to implement the same.

Despite its advantages, the FIGS. 4 and 7 array arrangements also have disadvantages. More specifically, pads are no longer equidistant from neighboring vias. That is, VBP technology moves vias closer to some pads. For example, looking at FIG. 7, it can be seen that a subject via 520′ is now much closer to a neighboring pad 519′-N3, i.e., FIG. 7's neighboring pad (519′-N3) distance D′_{NP} of 0.0055 inches is much closer in comparison to FIG. 6's D_{NP} of 0.0078 inches. In contrast, the pad 520′ is now further away from other neighboring pads (e.g., 519′-NI and 519′-N2).

A first problem with increased neighboring pad closeness is that, if there is any pad/ball mis-registration (see phantom line solder ball 122 in FIG. 7), there is high potential for electrical short-circuiting of the solder ball 122 to a neighboring (normally electrically isolated) via 520′ due to the misregistration. Even without mis-registration, the now closer proximity between normally electrically isolated pads (e.g., 519′-N1) and vias (e.g., 520′) results in a higher potential for solder ball collapsing and bridging between surrounding vias and/or traces. Collapsing/bridging problems as well as one example solution will be illustrated and discussed using the following several FIGs.

More particularly, attention is first directed to FIGS. 10 and 11. FIGS. 10 and 11 are simplified cross-sectional views 1000, 1100 as taken along (an extended) cross-sectional line 10-10 in FIG. 7 (to show three example solder balls), before and after the FIG. 7 arrangement is subjected to a BGA mounting operation. Such views are useful in illustrating example solder joint, solder mask and plugging arrangements according to a first example embodiment of the present invention, as well as example problems with the solder joints after a solder jointing operation.

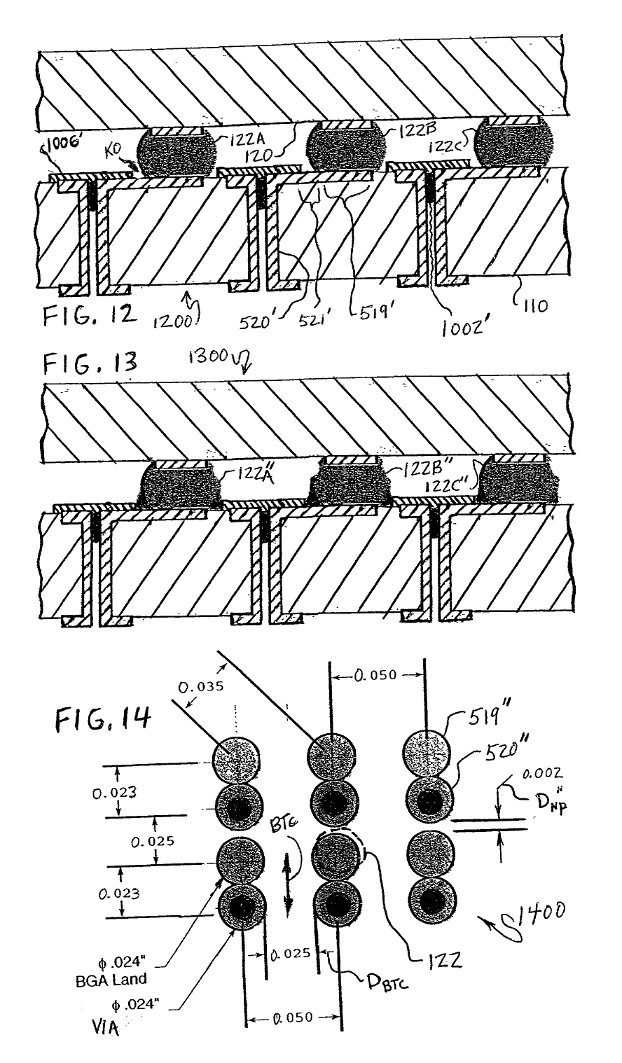

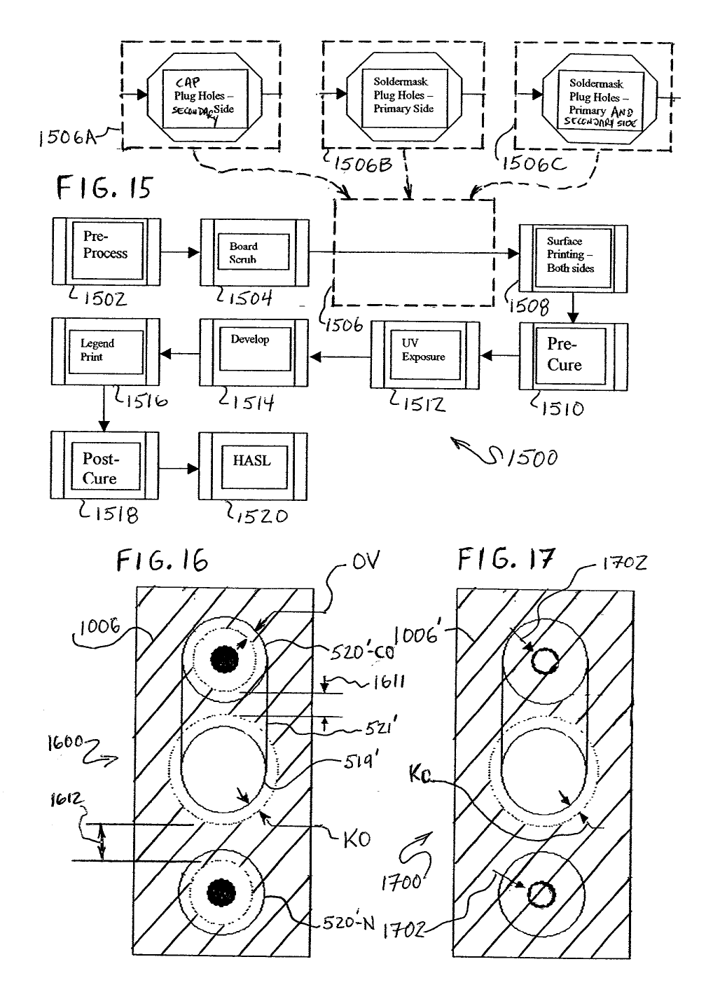

Shown within the arrangement 1000 is a portion of the FC die 120 and substrate 110 having three solder balls 122a, 122b, 122c sandwiched therebetween. A primary side of the substrate 110 is defined as a die-facing side of the substrate 110, whereas a secondary side is defined as the non-die-facing side. FIG. 10 also illustrates structures associated with each solder ball, for example, a die pad 1108, a substrate pad 519′, a PV-trace 521′ and a via 520′. The via 520′ includes a via-pad at least on the primary side surface of the substrate 110, as well as a passageway through-hole (coated with conductive material) extending at least partially through the substrate. The underfill material (125; FIGS. 1 and 5) is not shown in any of FIGS. 10 and 11 (or FIGS. 12-13) for sake of simplicity and clarity.

In addition to the above, FIG. 10 further illustrates caps (plugs also useable) 1002 applied on the secondary substrate surface to each of the vias 520′, in an attempt to minimize solder ball collapse and/or wicking (both described ahead) into the via passageways. As a further precaution against collapse and wicking, FIG. 10 further illustrates an example solder mask (SM) 1006, which is further clarified in FIG. 16.

Turning to FIG. 16, such is a simplified plan view of an example SM layout useable with the secondary-side-plugged substrate example embodiment of the present invention, i.e., such FIG. shows the areas to which a SM is applied with respect to one example pad 519′, interconnected trace 521′ and interconnected via 520′-CO, as well as a normally unconnected neighboring via 520′-N. The FIG. 16 plan view 1600 shows the SM 1006 having a layout pattern such that there is a keep out KO area (also shown in the cross-sectional FIG. 10 view) surrounding the pad 519′, whereas the SM slightly overlaps OV (also shown in the cross-sectional FIG. 10 view) onto both of a neighboring via 520′-N and a connected via 520′-CO. More particularly, the SM is essentially a containment mask to help contain bonding material (e.g., solder from the solder balls 122) to pad areas of the pad/via pairs during a bonding process for bonding portions of the VBP sub-array to another component.

FIG. 16 shows just one pad of the array, in relation to one connected via and one non-connected via. That is, with regard to the via 520′-CO, such is electrically connected to the pad 519′ via through the PV-trace 521′. Owing to the SM 1006 only partially covering the neighboring via 520′-N and connected via 520′-CO, the SM 1006 accordingly has narrow web portions 1611 and 1612 between the vias and the pad 519′. One problem with the narrow web portions 1611,1612, is that they are difficult to apply reliably (e.g., via a silk screening process). Often times, web application failures occur, for example where the web deposited has a very thin thickness (partial application failure), or is inadvertently absent altogether (total application failure). The application failures as well as the narrow web portions themselves, may contribute to solder-ball collapse and/or bridging during subsequent bonding (e.g., solder jointing) processes.

More specifically, whereas FIG. 10 illustrates the cross-sectional arrangement prior to heat or other bonding, FIG. 11 illustrates the FIG. 10 cross-sectional arrangement after a high pressure and heat (i.e., a high temperature thermo-bonding process). Three types of solder balls failures are illustrated with example collapse, bridging and/or open-circuiting problems. Turning first to the solder-ball 122A′, such is shown in a state of partial collapse, with solder bridging (melting) occurring onto its own via pad as well as slight solder wicking down into the via passageway. FIG. 7 shows an alternative example plan view of such a bridge in phantom-line form as 122BR. Further, FIG. 20 is magnified, partial cross-sectional view 2000 of FIG. 11's encircled area 20, such view being useful in explanation and understanding of a cracking phenomena with respect to a collapsed bridge solder ball.

More particularly, even with the partial collapse and bridging, the solder-ball 122A′ joint most likely would provide proper electrical connection, at least initially. That is, although connected solder bridges of this type do not result in initial electrical failures, they do represent a reliability concern due to the deformed solder joint after the reflow process. More particularly, the die 120, substrate 110 and other components (such as the solder-ball 122A′ joint) may be subjected to large number of stresses over a life-span (anticipated as 7 years) of the FC-PGA arrangement. For example, mechanical shocks (e.g., due to impacts, drops, etc.), vibrations, as well as thermal stresses.

Focusing on the thermal stresses, a large number of thermal expansion/contraction stresses will occur as the FC-PGA cycles on/off and heats/cools many times over its life-span. That is, since the die 120, substrate 110 and all the other components (die pad 1108, a substrate pad 519′, a PV-trace 521′, a via 520′ and solder-ball 122A′) are made of differing materials, shapes, etc., they will expand/contract at differing rates during heating/cooling resulting in the stresses. For example, it is felt that one major stress cause is a local thermal mismatch of solder/copper/FR4, as opposed to a BGA/PCB thermal mismatch. The crack is felt initiated by via pushing and pulling the solder fillet during the temperature cycles. Accordingly, it is felt that cracks may occur in almost all bridged solder joints at various locations.

Beyond theory, actual thermal testing has proven that stress cracks such as crack 2012 do occur along solder bridges and may worsen over time. There is a possibility that the crack 2012 will become sufficiently great so as to cause a splitting of the solder-ball 122A′ into two parts 122A′-1, 122A′-2 (FIG. 20), whereupon an intermittent or open-circuit electrical connection would occur to the via 520′ to result in an ultimate failure of the FC-PGA device. Alternatively to cracking, the resultant stresses may instead cause de-lamination of any of the laminated components (die pad 1108, a substrate pad 519′, a PV-trace 521′, a via 520′) from the die 120 or substrate 110, which each may represent another means of a disadvantageous electrical interruption.

Returning to FIG. 11, the middle solder-ball 122B′ illustrates another example type of partial collapse and bridging, this time with bridging and slight wicking occurring onto a neighboring, normally non-connected via. FIG. 7 shows an alternative example plan view of such a short-circuiting (SC) bridge in phantom-line form as 122SC. Such represents a disadvantageous short-circuiting bridge which typically result in electrical failure. Short-circuits can be identified by electrical testing and become a yield loss issue.

The final solder-ball 122C′ illustrates yet a third example type of collapse and bridging, this time with collapse being severe. While most collapsed solder balls do not cause opens and are still connected to the BGA package on a top of the solder balls, occasionally collapse may be severe whereupon an open-circuit would occur. Severe collapse may have several causes, e.g., imperfect SM application causing the solder ball to melt and spread widely; an uncapped/unplugged via causing major portions of the melted solder ball to wick down into the via passageway; multi-bridging onto several neighboring vias. Like the short-circuiting bridge, the open circuits typically result in electrical failure and can be identified by electrical testing, with failures becoming a yield loss issue.

Accordingly, it can be seen that solder-ball collapse and/or bridging are disadvantageous in numerous ways. In an effort to avoid such problems, attention turns next to another example embodiment using both primary-side via plugging and an un-webbed SM to provide improvement in reducing solder-ball collapse and/or bridging.

More particularly, FIGS. 12 and 13 are simplified cross-sectional views similar to those of FIGS. 10-11, such views being useful in illustrating example solder joint (SJ), solder mask (SM) and plugging arrangements according to a second example embodiment of the present invention. Shown in the FIG. 12 view 1200 is a primary side plug 1002′ within the via's passageway, as well as a SM 1006′. That is, the vias of the pad/via pairs have a via passageway thereof at least partially plugged to reduce entry of bonding material into the via passageway during a bonding process for bonding portions of the VBP sub-array to another component. The terms “plugs” or “plugging” (throughout the disclosure, and including the claims) are used generically to mean “plug”, “plugging”, “cap”, “capping” and other types of via clogging or blocking arrangements.

The plug may fill an entirety of the via's passageway, or alternatively, fill a lesser volume, e.g., 20%, 30%, 40%, 50%, etc. The plug 1002′ may be separately deposited, or may instead be SM 1006′ material which is forced (e.g., via silk-screening) down into the via passageway. A plug material may be selected which will not have any long term negative effects (e.g., such as corrosive, leakage effects) on the via passageway.

As to the SM, for further clarity, FIG. 17 (similar to FIG. 16) is a simplified plan view 1700 of an example SM layout (plugged-via SM) useable with the primary-side-plugged substrate example embodiment of the present invention. The new SM is a simple design change which is easily implemented (e.g., a new silk-screen stencil design). The FIG. 16 narrow webs (and problems associated therewith) are eliminated, in that the FIG. 17 arrows 1702 representatively show that the SM 1006 now covers at least a majority, if not an entirety or substantial entirety, of the via-pad. The KO area with respect to the pad 519′ is maintained, so as to facilitate a clean pad surface for good solder joint bonding.

Upon completion of the bonding operations, the FIG. 13 view 1300 shows minimal, if any, 122A″, 122B″, 122C″ ball collapse and no solder joint bridging when using both primary-side via plugging and an un-webbed SM. As to the minimal ball collapse, such may occur because of portions of the solder ball may melt into the KO areas defined by the SM (see KO in FIG. 12, and compare corresponding areas in FIG. 13). Accordingly, by plugging the solder mask material into the via from the primary side during the PCB manufacturing process, the narrow solder mask web areas are avoided, and the solder bridging virtually eliminated. That is, solder ball shape and solder ball jointing integrity are maintained to a higher degree.

The via plugging and un-webbed SM can be easily implemented in a PCB manufacturing process. More particularly, FIG. 15 is an example manufacturing process flow 1500 for printed circuit board (PCB) substrate production. Included are the example background steps of: pre-process 1502; board scrub 1504; surface printing 1508; pre-cure 1510, ultra-violet (UV) exposure 1512, development 1514, legend printing 1516, post cure 1518 and hot air surface leveling (HASL) 1520. FIG. 15 further shows an additional optional process flow 1506, as well as three example process flow alternatives with respect to three differing example embodiments of the present invention, for providing proper via plugging to the substrate.

More particularly, in a first process alternative 1506A, vias are capped (or plugged) on a secondary side of the substrate. Such alternative coincides with the arrangement illustrated with respect to FIGS. 10-11. In a second alternative 1506B, vias are plugged on a primary side of the substrate. Such alternative coincides with the arrangement illustrated with respect to FIGS. 1213. In a third alternative, vias are plugged on both a primary side and a secondary side of the substrate. Such can be accomplished by applying a SM to both the primary and secondary sides, and may be advantageous in an arrangement where a first BGA is used to bond the die 120 to the substrate 110 and a second BGA is used to bond the substrate 110 to another component (e.g., an interposer or a motherboard). Such would be advantageous to prevent solder balls from either of the first and second BGA from collapsing and wicking into the via passageways.

It should be readily apparent at this point that through the relatively minor changes of using ones or all of a VBP array, via plugging and an unwebbed SM, a mounting arrangement with the advantages of increased R-trace routing, increased substrate surface area for shaped impedances, and increased solder-ball collapse/bridging protection can be easily achieved.

Several other aspects of the FIG. 19 VBP breakout array layout with respect to practice of the present invention should be mentioned. First, it should be apparent to those skilled in the art, that the array area need not occupy an entirety of the area or be arranged as a single unified array. In fact, the FIG. 19 layout's array area is sub-divided into a plurality of sub-arrays. More particularly, FIG. 21 is a simplified plan layout 2100 designating (detailing) various areas of the FIG. 20 breakout layout. More particularly, if FIG. 21 is aligned with and laid over the FIG. 20 breakout layout, the various FIG. 21 lines delineate boundaries of various layout sub-arrays within FIG. 20. Such view is useful in explanation and understanding example sub-arrays. Each VBP sub-array may have a large plurality of pad/via pair members, for example, 20, 30, 40, 50 or even 60+members.

In defining the example sub-areas, an area A defined between dashed-line boxes 260 and 280 represents the aforementioned (FIG. 2 discussion) R-trace area in that it contains mainly R-traces (aimed mainly toward the die), but may include a few other types of items, e.g., pads, vias, VBP pairs, non-VBP pairs. In contrast, the areas B, C, D, E and F represent sub-array areas. Further, sub-array boundary lines 1292 and 1298 show that boundaries between adjacent sub-arrays may be substantially straight-lined, whereas lines 1294 and 1296 show that boundaries may be irregular in shape. In addition to boundaries, the FIG. 19 example clearly shows that embodiments of the present invention may be practiced with a plurality of VBP sub-arrays which may have pad/via pairs collinear-aligned in differing directions.

For example, the left E and right C VBP sub-arrays logically have pad/via pairs collinear-aligned mainly in a horizontal (X-direction) as resultant horizontal breakout trace channels (shown representatively by BTC_{E} and BTC_{C}) will advantageously align with and easily receive horizontal (X-direction) R-traces emanating from area A's left and right sides (see FIG. 19). Similarly, the top B and bottom D VBP sub-arrays logically have pad/via pairs collinear-aligned mainly in a vertical (Y-direction) as resultant vertical breakout trace channels (shown representatively by BTC_{B} and BTC_{D}) will advantageously align with and easily receive vertical (Y-direction) R-traces emanating from area A's top and bottom sides (see FIG. 19). Stated differently, the column and row directions defined for the sub-arrays within areas E and C are reversed as row and column directions, respectively, for the sub-arrays within areas B and D.

As a further feature, while the FIGS. 4 and 22 illustrate example embodiments show PRs as containing only pads and the VRs containing only vias, real-world practice (FIG. 19) of embodiments of the present invention are not limited thereto, and the terms PR and VR are not so constrained. More particularly, a PR may only substantially (mainly or chiefly; almost totally) include pads, but may have some pads missing and may include a few other types of items, e.g, vias. Similarly, a VR may just substantially (mainly or chiefly; almost totally) include vias, but may have some vias missing and may include a few other types of items, e.g, pads. Careful review of PRs and VRs within the FIG. 19 example BGA primary side breakout layout will reveal examples of the same.

Similar discussion may be made with respect to the FIGS. 4 and 22 CP versus the FIG. 19 CP, i.e., real-world CPs may just substantially (mainly or chiefly; almost totally) include VBP pairs, but may have some VBP pairs missing and may include a few other types of items, e.g., pads, vias, non-VBP pairs. That is, it should be readily apparent that from FIG. 19 that a VBP array or sub-array may be a non-complete (irregular, non-intact) array, in that a number of pads, vias and VBP pairs may be omitted from the array or replaced with other items.

As a final FIG. 19 feature discussed herein, the central sub-array area F contained within dashed-line rectangle 1290 contains a shifted, interleaved array like those illustrated in FIGS. 3 and 6. Such shows that sub-arrays within a particular implementation do not have to be of a same type, i.e., VBP sub-arrays can be mixed with other types of sub-arrays.

Discussion turns next to show that embodiments of the present invention may be practiced with other types of array dimensional layouts and with other types of VBP-pair shapes. More particularly, FIG. 14 is a simplified plan view 1400 similar to that of FIG. 7, such view illustrating another example VBP array layout. Different example array dimensions are provided, and pad-to-via (PV) traces have been eliminated such that the pads and vias are provided in a touching or overlapping arrangement. Accordingly, the FIG. 14 VBP pairs each have a FIG. 8 type of shape as opposed to a dumbbell shape of the FIG. 7 VBP pairs.

Further, FIG. 14's BTC has a larger 0.025″ channel clearance distance D_{BTC}, in comparison to FIG. 7's clearance of 0.019″, making FIG. 14 more advantageous over FIG. 7 in that more and/or larger traces may be included (i.e., FIG. 14 contains a higher percentage of available trace area). In contrast, FIG. 14's neighboring pad distance D″_{NP} has a smaller 0.002 clearance in comparison to FIG. 7's 0.0055″, making it less advantageous over FIG. 7 in that FIG. 14 may be more prone to solder-ball collapse and bridging (see FIG. 14's mis-registered phantom solder ball 122).

With regard to the example layouts, dimensions and clearances (e.g., neighboring pad/via clearances) discussed and illustrated with respect to all the example embodiments, of course, the layouts, dimensions and clearances used in any real-world embodiment and implementation will be highly dependent upon the manufacturing accuracy and tolerances of any manufacturing process used to manufacture the substrate (with the VBP array) as well as characteristics of any materials used (e.g., flow characteristics of the bonding material (solder)) and also any bonding process used in bonding of the VBP array to another component. Accordingly, layouts, dimensions and clearances may be decided on a case-by-case basis, with such decisions being well within the purview of one skilled in the art.

With regard to the arbitrary “column” and “row” designations illustrated or discussed throughout the disclosure and claimed in the claims, again it is stressed that such designations are arbitrary and easily interchanged. For example, if the FIG. 4 array is rotated 90° such that the VBP is provided in a row direction (as opposed to the FIG. 4 column direction), then the discussions associated with such FIG. may be appropriately adapted by interchanging the words “row” and “column.”

In concluding, reference in the specification to “one embodiment”, “an embodiment”, “example embodiment”, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments. Furthermore, for ease of understanding, certain method procedures may have been delineated as separate procedures; however, these separately delineated procedures should not be construed as necessarily order dependent in their performance, i.e., some procedures may be able to be performed in an alternative ordering, simultaneously, etc.

Further, at least a portion of the present invention (e.g., data and/or programming defining a desired VBP array layout) may be practiced as a software invention, implemented in the form of a machine-readable medium having stored thereon at least one sequence of instructions that, when executed, causes a machine to effect the invention. With respect to the term “machine”, such term should be construed broadly as encompassing all types of machines, e.g., a non-exhaustive listing including: computing machines, non-computing machines, communication machines, etc. Similarly, which respect to the term “machine-readable medium”, such term should be construed as encompassing a broad spectrum of mediums, e.g., a non-exhaustive listing including: magnetic medium (floppy disks, hard disks, magnetic tape, etc.), optical medium (CD-ROMs, DVD-ROMs, etc), etc.

This concludes the description of the example embodiments. Although the present invention has been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A via-between-pad (VBP) sub-array of a pad/via (PV) array layout, comprising:
a plurality of pad/via pairs arranged substantially in a column/row array pattern, wherein, for at least a majority of pad/via pairs of the plurality, a via of pads which are arranged in a same column has at least a portion of a body thereof interposed between neighboring pads in the same column.

2. A VBP sub-array as claimed in claim 1, wherein, for the at least a majority of pad/via pairs of the plurality, the via of the pads which are arranged in the same column has at least a majority of the body thereof interposed between the neighboring pads in the same column.

3. A VBP sub-array as claimed in claim 2, wherein the VBP sub-array is arranged in a substantially rectilinear array where, for the at least a majority of pad/via pairs of the plurality, the pad and via of pad/via pairs in a same column-direction have at least a majority of bodies thereof substantially collinear with one another, where pads of adjacent pad/via pairs in adjacent columns are substantially collinear with one another in a row-direction, and where vias of adjacent pad/via pairs in adjacent columns are substantially collinear with one another in the row-direction.

4. A VBP sub-array as claimed in claim 2, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

5. A VBP sub-array as claimed in claim 2, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein a number of pad-rows and a number of via-rows for a column are substantially equal.

6. A VBP sub-array as claimed in claim 2, further comprising routing trace (R-trace) channels of a predetermined width defined between columns of the pad/via pairs.

7. A VBP sub-array as claimed in claim 1, wherein, for the at least a majority of pad/via pairs of the plurality, the via of the pads which are arranged in the same column has an axis of the body thereof substantially collinear with axes of the bodies of the neighboring pads in the same column.

8. A VBP sub-array as claimed in claim 7, wherein the VBP sub-array is arranged in a substantially rectilinear array where, for the at least a majority of pad/via pairs of the plurality, pads of adjacent pad/via pairs in adjacent columns are substantially collinear with one another in a row-direction, and where vias of adjacent pad/via pairs in adjacent columns are substantially collinear with one another in the row-direction.

9. A VBP sub-array as claimed in claim 7, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

10. A VBP sub-array as claimed in claim 7, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row row substantially comprising vias of adjacent pad/via pairs, which vias are arranged substantially collinear with one another;
and wherein a number of pad-rows and a number of via-rows for a column are substantially equal.

11. A VBP sub-array as claimed in claim 7, further comprising routing trace (R-trace) channels of a predetermined width defined between columns of the pad/via pairs.

12. A VBP sub-array as claimed in claim 1, wherein the VBP array layout including the VBP sub-array is to interface with a bumped grid array (BuGA).

13. A VBP sub-array as claimed in claim 12, wherein the BuGA is one of a ball grid array (BGA), plastic BGA, (PBGA), ceramic BGA (CBGA) and organic land grid array (OLGA).

14. A VBP sub-array as claimed in claim 1, further comprising via-plugs wherein the vias of the pad/via pairs have a via passageway thereof at least partially plugged to reduce entry of bonding material into the via passageway during a bonding process for bonding portions of the VBP sub-array to another component.

15. A VBP sub-array as claimed in claim 14, wherein the via-plugs are provided on at least a primary VBP-sub-array side of a substrate.

16. A VBP sub-array as claimed in claim 1, further comprising a containment mask to help contain bonding material to pad areas of the pad/via pairs during a bonding process for bonding portions of the VBP sub-array to another component, wherein the containment mask masks at least a majority of the pad-area of each via-pad of the pad/via pairs.

17. A VBP sub-array as claimed in claim 16, wherein the containment mask masks substantially an entirety of the pad-area of each via-pad of the pad/via pairs.

18. An electronic component comprising:
a via-between-pad (VBP) sub-array of a pad/via (PV) array layout, comprising:
a plurality of pad/via pairs arranged substantially in a column/row array pattern, wherein, for at least a majority of pad/via pairs of the plurality, a via of pads which are arranged in a same column has at least a portion of a body thereof interposed between neighboring pads in the same column.

19. An electronic component as claimed in claim 18, wherein, for the at least a majority of pad/via pairs of the plurality, the via of the pads which are arranged in the same column has at least a majority of the body thereof interposed between the neighboring pads in the same column.

20. An electronic component as claimed in claim 19, wherein the VBP sub-array is arranged in a substantially rectilinear array where, for the at least a majority of pad/via pairs of the plurality, the pad and via of pad/via pairs in a same column-direction have at least a majority of bodies thereof substantially collinear with one another, where pads of adjacent pad/via pairs in adjacent columns are substantially collinear with one another in a row-direction, and where vias of adjacent pad/via pairs in adjacent columns are substantially collinear with one another in the row-direction.

21. An electronic component as claimed in claim 19, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

22. An electronic component as claimed in claim 19, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein a number of pad-rows and a number of via-rows for a column are substantially equal.

23. An electronic component as claimed in claim 19, further comprising routing trace (R-trace) channels of a predetermined width defined between columns of the pad/via pairs.

24. An electronic component as claimed in claim 18, wherein, for the at least a majority of pad/via pairs of the plurality, the via of the pads which are arranged in the same column has an axis of the body thereof substantially collinear with axes of the bodies of the neighboring pads in the same column.

25. An electronic component as claimed in claim 24, wherein the VBP sub-array is arranged in a substantially rectilinear array where, for the at least a majority of pad/via pairs of the plurality, pads of adjacent pad/via pairs in adjacent columns are substantially collinear with one another in a row-direction, and where vias of adjacent pad/via pairs in adjacent columns are substantially collinear with one another in the row-direction.

26. An electronic component as claimed in claim 24, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

27. An electronic component as claimed in claim 24, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row row substantially comprising vias of adjacent pad/via pairs, which vias are arranged substantially collinear with one another;
and wherein a number of pad-rows and a number of via-rows for a column are substantially equal.

28. An electronic component as claimed in claim 24, further comprising routing trace (R-trace) channels of a predetermined width defined between columns of the pad/via pairs.

29. An electronic component as claimed in claim 18, wherein the VBP array layout including the VBP sub-array is to interface with a bumped grid array (BuGA).

30. An electronic component as claimed in claim 29, wherein the BuGA is one of a ball grid array (BGA), plastic BGA, (PBGA), ceramic BGA (CBGA) and organic land grid array (OLGA).

31. An electronic component as claimed in claim 18, further comprising via-plugs wherein the vias of the pad/via pairs have a via passageway thereof at least partially plugged to reduce entry of bonding material into the via passageway during a bonding process for bonding portions of the VBP sub-array to another component.

32. An electronic component as claimed in claim 31, wherein the via-plugs are provided on at least a primary VBP-sub-array side of a substrate.

33. An electronic component as claimed in claim 18, further comprising a containment mask to help contain bonding material to pad areas of the pad/via pairs during a bonding process for bonding portions of the VBP sub-array to another component, wherein the containment mask masks at least a majority of the pad-area of each via-pad of the pad/via pairs.

34. An electronic component as claimed in claim 33, wherein the containment mask masks substantially an entirety of the pad-area of each via-pad of the pad/via pairs.

35. An electronic component as claimed in claim 18, wherein the electronic component is one of a die, a package substrate, a package interposer, a printed circuit board (PCB) and a PCB motherboard.

36. An electronic system, wherein at least one component thereof comprises:
a via-between-pad (VBP) sub-array of a pad/via (PV) array layout, comprising:
a plurality of pad/via pairs arranged substantially in a column/row array pattern, wherein, for at least a majority of pad/via pairs of the plurality, a via of pads which are arranged in a same column has at least a portion of a body thereof interposed between neighboring pads in the same column.

37. An electronic system as claimed in claim 36, wherein, for the at least a majority of pad/via pairs of the plurality, the via of the pads which are arranged in the same column has at least a majority of the body thereof interposed between the neighboring pads in the same column.

38. An electronic system as claimed in claim 37, wherein the VBP sub-array is arranged in a substantially rectilinear array where, for the at least a majority of pad/via pairs of the plurality, the pad and via of pad/via pairs in a same column-direction have at least a majority of bodies thereof substantially collinear with one another, where pads of adjacent pad/via pairs in adjacent columns are substantially collinear with one another in a row-direction, and where vias of adjacent pad/via pairs in adjacent columns are substantially collinear with one another in the row-direction.

39. An electronic system as claimed in claim 37, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

40. An electronic system as claimed in claim 37, wherein the VBP sub-array is arranged in a substantially rectilinear array where, for the at least a majority of pad/via pairs of the plurality, columns substantially comprise substantially aligned pad/via pairs where the pad and via of pad/via pairs in a same column-direction each have at least a majority of bodies thereof substantially collinear with one another, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein a number of pad-rows and a number of via-rows for a column are substantially equal.

41. An electronic system as claimed in claim 37, further comprising routing trace (R-trace) channels of a predetermined width defined between columns of the pad/via pairs.

42. An electronic system as claimed in claim 36, wherein, for the at least a majority of pad/via pairs of the plurality, the via of the pads which are arranged in the same column has an axis of the body thereof substantially collinear with axes of the bodies of the neighboring pads in the same column.

43. An electronic system as claimed in claim 42, wherein the VBP sub-array is arranged in a substantially rectilinear array where, for the at least a majority of pad/via pairs of the plurality, pads of adjacent pad/via pairs in adjacent columns are substantially collinear with one another in a row-direction, and where vias of adjacent pad/via pairs in adjacent columns are substantially collinear with one another in the row-direction.

44. An electronic system as claimed in claim 42, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row substantially comprising vias of adjacent pad/via pairs, which vias are arranged substantially collinear with one another;
and wherein pad-rows and via-rows are provided in a predetermined repetitive pattern along the column-direction.

45. An electronic system as claimed in claim 42, wherein the VBP sub-array is arranged in a substantially rectilinear array where, for the at least a majority of pad/via pairs of the plurality, columns substantially comprise collinear aligned pad/via pairs, and where each row is one of:
a pad-row substantially comprising pads of adjacent pad/via pairs, which pads are arranged substantially collinear with one another; and
a via-row row substantially comprising vias of adjacent pad/via pairs, which vias are arranged substantially collinear with one another;
and wherein a number of pad-rows and a number of via-rows for a column are substantially equal.

46. An electronic system as claimed in claim 42, further comprising routing trace (R-trace) channels of a predetermined width defined between columns of the pad/via pairs.

47. An electronic system as claimed in claim 36, wherein the VBP array layout including the VBP sub-array is to interface with a bumped grid array (BuGA).

48. An electronic system as claimed in claim 47, wherein the BuGA is one of a ball grid array (BGA), plastic BGA, (PBGA), ceramic BGA (CBGA) and organic land grid array (OLGA).

49. An electronic system as claimed in claim 36, further comprising via-plugs wherein the vias of the pad/via pairs have a via passageway thereof at least partially plugged to reduce entry of bonding material into the via passageway during a bonding process for bonding portions of the VBP sub-array to another component.

50. An electronic system as claimed in claim 49, wherein the via-plugs are provided on at least a primary VBP-sub-array side of a substrate.

51. An electronic system as claimed in claim 36, further comprising a containment mask to help contain bonding material to pad areas of the pad/via pairs during a bonding process for bonding portions of the VBP sub-array to another component, wherein the containment mask masks at least a majority of the pad-area of each via-pad of the pad/via pairs.

52. An electronic system as claimed in claim 51, wherein the containment mask masks substantially an entirety of the pad-area of each via-pad of the pad/via pairs.

53. An electronic system as claimed in claim 36, wherein the at least one component is one of a die, a package substrate, a package interposer, a printed circuit board (PCB) and a PCB motherboard.

54. A method for mounting grid array components comprising: implement one component with a via-between-pad (VBP) sub-array of a pad/via (PV) array layout, the VBP sub-array comprising a plurality of pad/via pairs arranged substantially in a column/row array pattern, wherein, for at least a majority of pad/via pairs of the plurality, the via of the pads which are arranged in the same column has an axis of the body thereof substantially collinear with axes of the bodies of the neighboring pads in the same column; and
apply via-plugs wherein the vias of the pad/via pairs have a via passageway thereof at least partially plugged to reduce entry of bonding material into the via passageway during a bonding process for bonding portions of the VBP sub-array to another component.

55. A method as claimed in claim 54, wherein the via-plugs are provided on at least a primary VBP-sub-array side of the component.

56. A method as claimed in claim 54, further comprising:
implement a containment mask on the component to help contain bonding material to pad areas of the pad/via pairs during a bonding process for bonding portions of the VBP sub-array to another component, wherein the containment mask masks at least a majority of the pad-area of each via-pad of the pad/via pairs.

57. A method as claimed in claim 56, wherein the containment mask masks substantially an entirety of the pad-area of each via-pad of the pad/via pairs.
